(19) United States
(12) Patent Application Publication
(10) Pub. No.: US 2019/0058108 A1
(43) Pub. Date: Feb. 21, 2019

(54) ION DIPOLES CONTAINING POLYMER COMPOSITIONS

(71) Applicant: SABIC Global Technologies B.V., Bergen op Zoom (NL)

(72) Inventors: Soma Guhathakurta, Bangalore (IN); Redha Bella, Thuwal (SA); Theo Hoeks, Bergen op Zoom (NL)

(21) Appl. No.: 15/770,694

(22) PCT Filed: Oct. 24, 2016
(86) PCT No.: PCT/IB2016/056389

§ 371 Date: Apr. 24, 2018

Related U.S. Application Data
(60) Provisional application No. 62/247,482, filed on Oct. 28, 2015.

(51) Int. Cl. H01L 41/193; H01L 41/45; H01L 41/113; H01L 41/09; H01L 41/04; H01B 3/44; C08K 5/5399; C08F 212/10

(52) U.S. Cl. CPC H01L 41/193; H01L 41/45; H01L 41/1132; H01L 41/09; G06F 3/016; H01B 3/442; C08K 5/5399; C08F 212/10; H01B 3/447; H01L 41/042

(57) ABSTRACT

A dielectric polymer, methods of making the dielectric polymer, and uses thereof (e.g. piezoelectric sensors and/or actuators) are described. The dielectric polymer includes a polymeric matrix (e.g. a copolymers of styrene and acrylonitrile SAN, or a terpolymer of the former with methyl methacrylate MMA-SAN) derived from at least one polymerizable vinyl monomer and an ionic liquid that includes an organic cation and a balancing anion (e.g. 1-butyl-3-methylimidazolium hexafluorophosphate BMMMPF6). The ionic liquid is compatible with the at least one polymerizable vinyl monomer and the concentration of the ionic liquid in the dielectric polymeric composition ranges from 0.5 wt. % to less than 30 wt. %.

### CROSS REFERENCE TO RELATED APPLICATIONS

This application claims the benefit of priority of U.S. Provisional Patent Application No. 62/247,482, filed Oct. 28, 2015, which is hereby incorporated by reference in its entirety.

### BACKGROUND OF THE INVENTION

### A. Field of the Invention

The invention generally concerns a dielectric polymeric composition that includes a polymeric matrix and an ionic liquid. In particular, the invention relates to a polymeric matrix derived from at least one polymerizable vinyl monomer and an ionic liquid that includes an organic cation and a balancing anion. The ionic liquid is compatible with the at least one polymerizable vinyl monomer and the concentration of the ionic liquid in the dielectric polymeric composition can range from 0.5 wt. % to less than 30 wt. %.

### B. Description of Related Art

Piezoelectric materials are the key components of electromechanical transducers (sensors and actuators) for automatic control systems, and measurement and monitoring systems. Currently, lead zirconate titanate (PZT) and barium titanate are the most common piezoelectric materials due to their high piezoelectric response and low input voltage requirement. These materials, however, are heavy, brittle, pose some environmental challenges (e.g., lead toxicity), and are difficult and expensive to produce on a commercial scale. Vinylidene fluoride based piezoelectric polymers, on the other hand solve some of these problems by offering mechanical flexibility, ease of processing, however, are also limited for their low piezoelectric response and high input voltage, an alternate solution to the problem associated with input voltage requirement, has been to use ionic electroactive polymers (EAP) (conductive polymers) based on ion gels in ionic EAP actuators. By way of example, Watanabe et al., in “Ion Gels Prepared by In situ Radical Polymerization of Vinyl Monomers in an Ionic Liquid and Their Characterization as Polymer Electrolytes”, J. Am. Chem. Soc. 2005, 127, 4976 describes in situ free radical polymerization of compatible vinyl monomers in a room temperature ionic liquid, 1-ethyl-3-methyl imidazolium bis(trifluoromethane sulfonyl)imide (EMITFSI) to afford a polymer electrolytes. Polymer gels obtained by the polymerization of methyl methacrylate (MMA) in EMITFSI in the presence of a small amount of a cross-linker gave self-standing, flexible, and transparent films with ionic conductivity of 10⁻² S·cm⁻¹. The operation of the ion gel actuator is driven by diffusion and migration of ions, which requires high ionic liquid loading (about 70 wt. %) to reach a desired conductivity. While ionic EAPs need low voltage for activation (e.g., 1 to 2 V), they suffer in response speed due to the migration of ions. The operation of piezoelectric material is governed by change in polarization, which is manifested in their rapid response. These materials are capable of sustaining the polarization upon removal of DC voltage (remanent polarization). The biggest challenge with these polymer based materials is the requirement of high input voltage (50-150 V/μm) for polarization, which is a critical safety issue.

### SUMMARY OF THE INVENTION

A discovery has been made that solves the problems associated with high input voltage requirements with the currently prevailing conventional polymer based dielectric materials and piezoelectric materials. The inventive material can be used in piezoelectric applications and can be a substitute for the existing materials such as PZT, PVDF, and the like, offering additional benefits and/or properties. To date, ions are exploited for developing ionically conducting polymer matrixes. In contrast to this conventional technology, the present discovery is premised on using an ionic liquid as source of ion dipoles to generate giant remanent polarization in a polymer matrix (remanent polarization is directly proportional to piezoelectric response). The source of the ion dipoles is an ionic liquid made up of organic cations and balancing anions that are incorporated into the polymeric matrix at an amount of less than 30 wt. %, which is believed to limit or prevent the matrix from being conductive. The dielectric polymeric composition of the present invention, which is a can be used for piezoelectricity related applications, provides an elegant composition that has high polarization when applying low voltage, can be transparent, and can be formed into thin films which make the compositions attractive for use in piezoelectric devices. Notably, the high polarization when applying low voltage is achieved by creating ion dipoles in the polymer matrix. High polarization under low input voltage can be achieved with the dielectric polymeric compositions through 1) the combination of specific polymers and ionic liquids 2) specific concentrations of the polymers and ionic liquids, and/or 3) a method of incorporating the ionic liquids into the polymeric matrix. The dielectric polymeric compositions of the present invention offer the advantages of low voltage polarization, transparency, ease of forming ability, etc. Notably, as shown in non-limiting instances in the Examples, the resulting dielectric polymeric compositions demonstrated high remanent polarization.

In one aspect of the invention, the dielectric polymeric composition is described. The dielectric polymeric composition can include a polymeric matrix derived from at least one polymerizable vinyl monomer and an ionic liquid. The ionic liquid can be an organic cation and a balancing anion, which is miscible or partially miscible in the polymeric matrix and/or compatible with the vinyl monomer. The concentration of the ionic liquid in the dielectric polymeric composition can range from 0.5 wt. % to less than 30 wt. % (e.g., 5 wt. % to 20 wt. %, or 10 wt. % to 15 wt. %, preferably 5 wt. %). The dielectric polymeric composition is capable of a polarization of greater than 30 μC/cm², 50 μC/cm², 80 μC/cm², preferably great than 300 μC/cm², or more preferably greater than 700 μC/cm² upon the application of an electric field of less than 30 kilovolts per centimeter (KV/cm). In a particular aspect, the polymeric matrix is formed, in situ, in the presence of the ionic liquid and in the absence of a solvent. The organic cation can be an organic compound that includes a heteroatom (e.g., organonitrogen, organophosphorous, organosulfur compounds and the like). The organic cation can be acyclic or cyclic. Non-limiting examples of organic cations include imidazolium compounds, N-alkylpyridinium compounds, N,N-dialkylpyrrolidinium compounds, piperidinium compounds, morpholinium compounds, trialkylsulfonium compounds, tetraalkylphosphonium compounds, and arylphospohium compounds, combinations thereof, preferably, the organic cation includes an imidazolium or a substituted imidazolium having a general structure of:

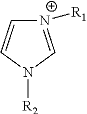

where R₁ and R₂ are each hydrogen or an alkyl group.

R₁ and R₂ can be the same or different. In some embodiments, R₁ is methyl and R₂ is an alkyl group having 1 to 10 carbon atoms, 2 to 8 carbon atoms, preferably, 3 to 5 carbon atoms. In a particular aspect R₁ is methyl and R₂ is butyl. The balancing anion of the ionic liquid can include any compound that can balance the charge of the organic cation. Non-limiting examples of anion include halogenated phosphate, a chlorate, an alkyl sulfate, a dicyanamide, a bis(trifluoromethanesulfonyl)imide, a bis(pentafluoroethanesulfonyl)imide, a tetrafluoroborate, a trifluoromethanesulfonate, a trifluoromethaneacetate, carboxylate, preferably hexafluorophosphate. The polymerizable vinyl monomer can have a general structure of

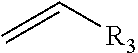

where R₃ can be a hydrogen, an alkyl group, an aryl group, a substituted aryl group, an alkylaryl, a cyano group or any combination thereof.

In some embodiments, the polymeric matrix can be a copolymer derived from two vinyl monomers. At least one of the vinyl monomers can include styrene or derivatives thereof, acrylonitrile or derivatives thereof, or any mixture thereof. In certain aspects, the dielectric polymeric composition can include 70 wt. % to 80 wt. % of styrene, 20 wt. % to 30 wt. % of acrylonitrile and 5 wt % to 15 wt. % of ionic liquid, preferably 75 wt. % of styrene, 25 wt. % of acrylonitrile, and 10 wt. % of ionic liquid. In certain embodiments, the polymeric matrix can be a terpolymer derived from an acrylate monomer (e.g., methyl acrylate, ethyl acrylate, methacrylates, methyl methacrylate, butyl methacrylate, preferably, methyl methacrylate, or any combination thereof) and the two vinyl monomers. For example, the dielectric polymeric composition can include 30 wt. % to 40 wt. % of methyl methacrylate, 35 wt. % to 45 wt % of styrene, 20 wt. % to 30 wt. % of acrylonitrile and 5 wt. % to 20 wt. % of ionic liquid. In one particular embodiment, the dielectric polymeric composition consists essentially of or consists of the ionic liquid and the polymeric matrix. The dielectric polymeric composition can be transparent and/or have remanent polarization. The clarity of the dielectric polymeric composition can be tuned based on the selection and combination of monomers. In one embodiment, the dielectric polymeric composition can have a glass transition temperature Tg of 50 to 96° C., a dielectric constant (ε) at 1 KHz of 5 to 30, a dielectric breakdown (kV/cm) of 10 to 60; and/or a remanent polarization (μC/cm²) of 30 to 785 after removal of an electric field of 10 to 30 KV/cm. The dielectric polymeric composition of the present invention can be in the form of a film or a sheet (i.e., a dielectric polymeric material) Apparatus and electronic devices that include the dielectric polymeric composition (material) of the present invention are descripted. Such devices can be a sensor, a transducer, an energy harvester, or a actuator. In a preferred embodiment, the apparatus or device is a piezoelectric device that includes any one of the dielectric polymeric compositions of the present invention is described. The piezoelectric device can be a piezoelectric sensor, a piezoelectric transducer, a piezoelectric energy harvester, or a piezoelectric actuator.

In one aspect of the present invention, a method for making, in situ, a dielectric polymeric composition of the present invention can include (a) subjecting a mixture comprising an ionic liquid and monomeric material that includes at least one polymerizable vinyl monomer to polymerization conditions (e.g., a temperature ranging from 30° C. to 100° C.), and (b) forming a polymeric matrix (e.g., a Tg miscible blend). The ionic liquid is fully miscible or partially miscible with the polymeric matrix, compatible with at least one polymerizable vinyl monomer, and, in some instances, dissolved in the vinyl monomer prior to step (a). The amount of ionic liquid can range from 0.5 wt. % to less than 30 wt. %. The mixture can include a free radical initiator (e.g., azobisisobutyronitrile, benzoyl peroxide, di-tert-butyl peroxide, tert-amyl peroxybenzoate, phenyl-azo-triphenylmethane, cumyl peroxide, acetyl peroxide, lauroyl peroxide, tert-butylhydroperoxide, tert-butyl perbenzoate and any combination thereof, preferably, azobisisobutyronitrile, or combinations thereof). In some embodiments, the polymerization mixture consists essentially of or consists of the ionic liquid, the free radical initiator, and the monomeric material.

The term “miscible” refers to substances that when mixed or combined together form a homogenous phase. By way of example, ionic liquids that are miscible in the polymeric matrices of the present invention can result in a homogenous phase, thereby resulting in a polymer matrix having a single thermal transition temperature. The single thermal transition temperature can be a glass transition temperature.

The phrase “partially immiscible” refers to substances that when mixed or combined together form a mixture of phases. Ionic liquids that are partially immiscible in the polymeric matrices of the present invention can result in a heterogeneous or homogeneous phase or phases, thereby resulting in a polymer matrix having more than one thermal transition temperature (Tg, Tm) corresponding to the individual components.

The term “immiscible” refers to substances that when mixed or combined together do not form a homogenous phase. By way of example, ionic liquids that are immiscible in the polymeric matrices of the present invention can result in a heterogeneous phase or phases, thereby resulting in a polymer matrix having more than one thermal transition corresponding to the individual components. This transition may or may not be glass transition temperature.

The phrase “wherein the ionic liquid is compatible with the at least one polymerizable vinyl monomer,” refers to the polymerizable vinyl monomer being at least partially miscible, preferably fully miscible, when mixed or combined with the ionic liquid.

The term “piezoelectric material” or “dielectric polymeric material” refers to materials that have the ability to generate an electric charge in response to applied mechanical stress and/or the ability to respond to an electric charge by changing stress. Fox example, with a dielectric polymeric material and/or a piezoelectric material stress can be used to create electric charge, or electric charge can be used to create stress.

The term “about” or “approximately” are defined as being close to as understood by one of ordinary skill in the art. In one non-limiting embodiment, the terms are defined to be within 10%, preferably within 5%, more preferably within 1%, and most preferably within 0.5%.

The term “substantially” and its variations are defined to include ranges within 10%, within 5%, within 1%, or within 0.5%.

The terms “wt. %”, “vol. %”, or “mol. %” refers to a weight, volume, or molar percentage of a component, respectively, based on the total weight, the total volume of material, or total moles, that includes the component. In a non-limiting example, 10 grams of component in 100 grams of the material is 10 wt. % of component.

The terms “inhibiting” or “reducing” or “preventing” or “avoiding” or any variation of these terms, when used in the claims and/or the specification includes any measurable decrease or complete inhibition to achieve a desired result.

The term “effective,” as that term is used in the specification and/or claims, means adequate to accomplish a desired, expected, or intended result.

The use of the words “a” or “an” when used in conjunction with any of the terms “comprising,” “including,” “containing,” or “having” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The dielectric polymeric composition of the present invention can “comprise,” “consist essentially of,” or “consist of” particular ingredients, components, compositions, etc. disclosed throughout the specification. With respect to the transitional phase “consisting essentially of,” in one non-limiting aspect, a basic and novel characteristic of the dielectric polymeric composition of the present invention is that it has remanent polarization. Dielectric polymeric composition can be used interchangeable in the specification with dielectric polymeric material.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description. In further embodiments, features from specific embodiments may be combined with features from other embodiments. For example, features from one embodiment may be combined with features from any of the other embodiments. In further embodiments, additional features may be added to the specific embodiments described herein.

### BRIEF DESCRIPTION OF THE DRAWINGS

Advantages of the present invention may become apparent to those skilled in the art with the benefit of the following detailed description and upon reference to the accompanying drawings.

FIG. 1 shows proton nuclear magnetic resonance (¹H NMR) spectra of dielectric polymeric composition of the present invention have 20 wt. % ionic liquid.

FIGS. 2A and 2B show the optical clarity of dielectric polymeric compositions of the present invention.

FIGS. 2C and 2D show transmission electron micrographs of the compositions of FIGS. 2A and 2B.

FIG. 3 shows graphs of relative permittivity (dielectric constant) versus frequency for a comparative polymeric sample and three dielectric polymeric compositions of the present invention.

FIG. 4 shows graphs of tan (delta) versus frequency for a comparative polymeric sample and three dielectric polymeric compositions of the present invention.

FIG. 5A is a P-E hysteresis loops measured at room temperature of a comparative polymer without ionic liquid.

FIG. 5B is a P-E hysteresis loops measured at room temperature of a dielectric polymeric composition of the present invention containing 5 wt. % ionic liquid.

FIG. 5C is a P-E hysteresis loops measured at room temperature of a dielectric polymeric composition of the present invention containing 10 wt. % ionic liquid.

FIG. 6 is an illustration showing an array of dielectric polymeric material-based actuators according to one embodiment of the disclosure.

FIG. 7 is an illustration showing an array of dielectric polymeric material-based actuators receiving a direct current (DC) stimulation to cause static displacement to generate touch feedback according to one embodiment of the disclosure.

FIG. 8 is an illustration showing an array of dielectric polymeric material-based actuators integrated into a display of an electronic device according to one embodiment of the disclosure.

FIG. 9 is a block diagram showing operation of an array of dielectric polymeric material-based actuators from a controller according to one embodiment of the disclosure.

FIG. 10 is an illustration showing a texture presented on a display of an electronic device using an array of dielectric polymeric material-based actuators receiving a direct current (DC) stimulation according to one embodiment of the disclosure.

FIG. 11 is an illustration of a room with a dielectric polymeric material-based light switch with an array of dielectric polymeric material-based touch sensors according to one embodiment of the disclosure.

While the invention is susceptible to various modifications and alternative forms, specific embodiments thereof are shown by way of example in the drawings and may herein be described in detail. The drawings may not be to scale.

### DETAILED DESCRIPTION OF THE INVENTION

A discovery has been made that solves the problems associated with high input voltage requirement for polymeric dielectric materials (e.g., piezoelectric materials). The solution resides in the use of an ionic liquid that is miscible (e.g., partially or completely miscible) with a desired polymeric matrix. The ionic liquid includes an organic cation and a balancing anion. The dielectric polymeric compositions of the present invention have good dielectric properties and physical properties that make them useful for use in flexible electronic devices. Notably, the dielectric polymeric compositions of the present invention, which can be used for piezoelectricity related applications, can have high polarization at low voltage due to 1) an ionic liquid concentration below 30 wt. % and 2) mixing the ionic liquid with the polymer precursors and then polymerizing the polymers in situ to incorporate the ionic liquid into the polymeric matrix.

These and other non-limiting aspects of the present invention are discussed in further detail in the following sections.

### A. Dielectric Polymeric Composition

The dielectric polymeric compositions of the present invention can be prepared as a polymeric matrix that contains an ionic liquid that is miscible or at least partially miscible with the polymeric matrix (e.g., a Tg miscible blend). The ionic liquid can be compatible with at least one of the monomers that are used to prepare the polymeric matrix. The concentration of the ionic liquid in the polymeric matrix can range from 0.5 wt. % to 30 wt. %, or 0.5 wt. %, 1 wt. %, 1.5 wt. %, 2 wt. %, 3 wt. %, 4 wt. %, 5 wt. %, 6 wt. %, 7 wt. %, 8 wt. %, 9 wt. %, 10 wt. %, 11 wt. %, 12 wt. %, 13 wt. %, 14 wt. %, 15 wt. %, 16 wt. %, 17 wt. %, 18 wt. %, 19 wt. %, 20 wt. %, 21 wt. % 22 wt. % 23 wt. %, 24 wt. %, 25 wt. % 26 wt. %, 27 wt. %, 28 wt. %, 29 wt. % or less than 30 wt. %. The ionic liquid can be incorporated in the polymeric matrix. The dielectric polymeric composition can have a glass transition temperature Tg of 50 to 96° C., 55 to 90° C., 60 to 80° C., 65 to 75° C. or any range or value there between. In some instances, the clarity of the dielectric polymeric composition can be tuned through selection of specific monomers and ionic liquids. For example, a combination of an ionic liquid with one or more vinyl monomers (e.g., styrene and acrylonitrile) and an acrylate monomer (e.g., methyl methacrylate) can provide a transparent dielectric polymeric composition while a combination of two vinyl monomers (styrene and acrylonitrile) with an ionic liquid can be opaque.

Further, and without wishing to be bound by theory, it is believed that the ionic liquid imparts elasticity to the dielectric polymeric composition. By having elasticity, the dielectric polymeric composition is able to resume its normal shape after being stretched or compressed, thereby making the dielectric polymeric composition suitable for flexible applications (e.g., electronic devices). Due to its elasticity, application of pressure can deform the dielectric polymeric composition, thereby pushing the ion dipoles (organic cations and anions) of the ionic liquid closer together or further apart, upsetting the balance of positive and negative charge, and causing net electrical charges to appear. This effect carries through the whole structure so net positive and negative charges appear on opposite, outer surfaces of the polymeric composition. The dielectric polymeric composition can also be used for reverse-piezoelectric effects. When a voltage is applied across a dielectric polymeric composition, the ion dipoles inside the polymeric matrix are subject to “electrical pressure,” causing the ion dipoles to move to rebalance the charge, thereby causing the dielectric polymeric composition to deform (slightly change shape). Piezoelectric behavior can be assessed through the dielectric properties of the composition. The dielectric properties of the dielectric polymeric compositions are suitable for use in piezoelectric devices. In some embodiments, the dielectric constant (ε) of the composition can range from 5 to 30, 6 to 25, 7 to 20, 8 to 15, or 10 to 12 at 1 KHz. The dielectric polymeric composition can be capable of a polarization of greater than 30 μf/cm², 50 μC/cm², 100 μc/cm², 200 μC/cm², 300 μC/cm², 350 μC/cm², 400 μC/cm², 450 μC/cm², 500 μC/cm², 550 μC/cm², 600 μC/cm², 650 μC/cm², 700 μC/cm², or 750 μC/cm², preferably greater than 300 μC/cm², or more preferably greater than 700 μC/cm² upon the application of an electric field of less than 30 KV/cm (e.g., 1 KV/cm, 2 KV/cm, 5 KV/cm, 10 KV/cm, 15 KV/cm, 20 KV/cm, 25 KV/cm or 30 KV/cm). A dielectric breakdown (kV/cm) of the dielectric polymeric composition can range from 10 to 60, 15 to 50, or 20 to 40. A remanent polarization (μC/cm²) of the dielectric polymeric composition can range from 30 to 785 after removal of an electric field of 10 to 30 KV/cm. Such electrical, physical, and optical properties of the composition provide a material that can be used in a variety of dielectric devices (e.g., piezoelectric sensor, a piezoelectric transducer, a piezoelectric energy harvester, or a piezoelectric actuator).

1. Ionic Liquids

The ionic liquid of the present invention can be any compound that includes an organic cation and a balancing anion having the general structure of: Z⁺ X⁻ where Z+ is an organic cation, and X⁻ is an anion. In a preferred embodiment, Z⁺ X⁻ is 1-butyl-3-methylimidazolium hexafluorophosphate. Ionic liquids can be synthesized using known organic synthesis methods or purchased from a commercial source (e.g., Sigma-Aldrich®, USA).

X⁻ can be a halide, a nitrate, a phosphate (e.g., halogenated phosphate and hexafluorophosphate), an imide (e.g., a bis(trifluoromethanesulfonyl)imide, a bis(pentafluoroethanesulfonyl)imide), a dicyanamide, a borate (e.g., tetrafluoroborate), a phosphazine, an acetate (e.g., trifluoromethaneacetate), a sulfonate (e.g., trifluoromethanesulfonate), a sulfate, an alkyl sulfate, a carboxylate, or any combination thereof.

Z+ can be an onium compound, a phosphonium compound, a sulfonium compound, and any 5 or 6 membered heterocyclic ring having 1 to 3 heteroatoms as ring members selected from nitrogen, oxygen or sulfur, where one of the atoms in the heterocyclic ring of the cation can be substituted with one or more halides, oxygen, nitrogen, sulfur, phosphorus, alkanes, esters, ethers, ketones, carbonyls, alkoxyalkanes, alkenes, aryls, nitriles, silanes, sulfones, thiols, phenols, hydroxyls, amines, imides, aldehydes, carboxylic acids, alkynes, carbonates, and anhydrides. The carbon or hydrogen atoms in the groups can be further substituted with halides, oxygen, nitrogen, sulfur, phosphorus, alkanes, esters, ethers, ketones, carbonyls, alkoxyalkanes, alkenes, aryls, nitriles, silanes, sulfones, thiols, phenols, hydroxyls, amines, imides, aldehydes, carboxylic acids, alkynes, carbonates, and anhydrides, or any combination thereof. Non-limiting examples of onium compounds include substituted or unsubstituted imidazolium compound, a substituted or unsubstituted N-alkylpyridinium compound, a substituted or unsubstituted N,N dialkyl pyrrolidinium compound, a substituted or unsubstituted piperidinium compound, a substituted or unsubstituted morpholinium compound. Non-limiting example of a sulfonium compound includes a trialkyl sulfonium compound. Non-limiting examples of a phosphonium compound includes a tetraalkyl phosphonium compound and/or an aryl phosphonium compound. In some embodiments, the organic cation can be substituted or unsubstituted imidazole compound having a general structure (I) of:

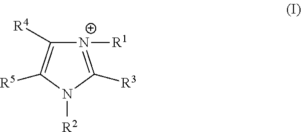

where R¹, R², R³, R⁴, and R⁵ are individually hydrogen or a linear or branched alkyl group having 1 to 20 carbon atoms. In one aspect of the invention, R¹ is methyl and R² is a linear or branched alkyl group having 1 to 10 carbon atoms, 2 to 8 carbon atoms, 1, 2, 3, 4, 5, 6, 7, 8, 9 10 carbon atoms, preferably 3 to 5 carbon atoms, and R³, R⁴, and R⁵ are hydrogen. In a preferred aspect of the invention, R₁ is methyl (1 carbon atom) and R₂ is butyl (4 carbon atoms), which is 1-butyl-3-methylimidazolium.

2. Polymeric Precursors

The dielectric polymeric composition of the present invention can include precursor compounds having free radical reactive ethylenically functional groups that include monomers, oligomers, polymers, or mixtures thereof having one or more free radically reactive ethylenically functional groups. Suitable compounds contain at least one ethylenically group capable of undergoing addition polymerization. Non-limiting examples of ethylenically functional groups include a vinyl group and acrylates. Polymeric precursor materials can be made using known polymeric methods or obtained from a commercial vendor (Sigma-Aldrich®, USA, or SABIC Innovative Plastics).

Vinyl monomers can have a general structure of:

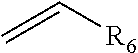

where R⁶ is a hydrogen, an alkyl group, an aryl group, a substituted aryl group, an alkylaryl, a cyano group or any combination thereof. Non-limiting examples of vinyl monomers include styrene or derivatives thereof, acrylonitrile or derivatives thereof, diallyl phthalate, divinyl succinate, divinyl adipate and divinyl phthalate, or any mixture thereof. In a preferred embodiment, acrylonitrile and styrene are used.

Acrylates can have the general structure of:

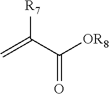

where R⁷ and R⁸ are individually hydrogen, substituted or unsubstituted alkyl, substituted or unsubstituted aryl, alkylaryl, or mixtures thereof. As used within the context of the present application an acrylate compound is not considered a vinyl compound. Non-limiting example of acrylates include acrylic acid esters, methacrylic acid esters, hydroxy-functional acrylic acid esters, hydroxy-functional methacrylic acid esters, and combinations thereof. Such free radically polymerizable compounds include mono-, di- or poly-(meth)acrylates (i.e., acrylates and methacrylates), methyl (meth)acrylate, ethyl (meth)acrylate, isopropyl (meth)acrylate, n-hexyl (meth)acrylate, stearyl (meth)acrylate, allyl (meth)acrylate, 1,3-propanediol di(meth)acrylate, trimethylolpropane tri(meth)acrylate, 1,2,4-butanetriol tri(meth)acrylate, 1,4-cyclohexanediol di(meth)acrylate, sorbitol hex(meth)acrylate, tetrahydrofurfuryl (meth)acrylate, bis[1-(2-acryloxy)]-p-ethoxyphenyldimethylmethane, bis[1-(3-acryloxy-2-hydroxy)]-p-propoxyphenyldimethylmethane, and trishydroxyethyl-isocyanurate tri(meth)acrylate; (meth)acrylamides (e.g., acrylamides and methacrylamides) such as (meth)acrylamide, methylene bis-(meth)acrylamide, and diacetone (meth)acrylamide; urethane (meth)acrylates and mixtures thereof. In a preferred embodiment, methyl methacrylate is used.

### B. Polymerization

The dielectric polymeric composition can be prepared using an in situ polymerization process. A mixture of the ionic liquid, a polymeric precursor material, and a free radical initiator can be subjected to conditions sufficient to polymerize the polymeric precursor material, thereby forming the dielectric polymeric composition. The polymeric precursor material can be a vinyl polymerizable monomer, two or more monomers (e.g., 2, 3, 4, 5, or more monomers) that are the same or different where one of the polymerizable monomers is a vinyl monomer, two or more vinyl monomers and an acrylate monomer, or the like. Non-limiting example, blended polymeric precursor material include styrene and acrylonitrile blend, or a styrene, acrylonitrile and methyl methacrylate blend, or the like. In one aspect of the invention, the mixture can include 70 wt. %, 71 wt. %, 72 wt. %, 73 wt. %, 74 wt. %, 75 wt. %, 76 wt. %, 77 wt. %, 78 wt. % 79 wt. % 80 wt. % or any value there between of styrene, 20 wt. % 21 wt. %, 22 wt. %, 23 wt. %, 24 wt. %, 25 wt. %, 26, wt. %, 27 wt. %, 28 wt. % 29 wt. %, 30 wt. % or any value there of acrylonitrile, and 5 wt %, 6 wt. %, 7 wt. %, 8 wt. %, 9 wt. %, 10 wt. %, 11 wt. % 12 wt. %, 13 wt. % 14 wt. %, 15 wt. % or any value there between of ionic liquid. In a preferred embodiment, 75 wt. % of styrene, 25 wt. % of acrylonitrile, and 10 wt. % of ionic liquid is used.

In another non-limiting example, the mixture can include 30 wt. %, 31 wt. %, 32 wt. %, 33 wt. %, 34 wt. %, 35 wt. %, 36 wt. %, 37 wt. %, 38 wt. %, 39 wt. %, 40 wt. % or any value there between of methyl methacrylate, 35 wt. %, 36 wt. %, 37 wt. %, 38 wt. %, 39 wt. %, 40 wt. %, 41 wt. %, 42 wt. %, 43 wt. %, 44 wt. %, 45 wt. % or any value there between of styrene, 20 wt. % 21 wt. %, 22 wt. %, 23 wt. %, 24 wt. %, 25 wt. %, 26, wt. %, 27 wt. %, 28 wt. % 29 wt. %, 30 wt. % or any value there between of acrylonitrile, and 5 wt %, 6 wt. %, 7 wt. %, 8 wt. %, 9 wt. %, 10 wt. %, 11 wt. % 12 wt. %, 13 wt. % 14 wt. %, 15 wt. %, 16 wt. %, 17 wt. %, 18 wt. %, 19 wt. %, 20 wt. % or any value there between of ionic liquid. The mixture can include about 0.01 to 0.5 wt. %, or about 0.2 wt. % of initiator. The initiator can be any initiator suitable for free radical polymerization reactions. Non-limiting examples of initiators include azobisisobutyronitrile, benzoyl peroxide, di-tert-butyl peroxide, tert-amyl peroxybenzoate, phenyl-azo-triphenylmethane, cumyl peroxide, acetyl peroxide, lauroyl peroxide, tert-butylhydroperoxide, tert-butyl perbenzoate and any combination thereof, preferably azobisisobutyronitrile.

The conditions for polymerization can be any conditions (e.g., bulk polymerization process) that will initiate free radical polymerization in situ. Such conditions include a temperature of from 30 to 100° C., or 40° C., 50° C., 60° C., 70° C., 80° C., 90° C. or any temperature there between. Without wishing to be bound by theory, it is believed that the radical polymerization of the monomers form a polymeric matrix that encapsulates or incorporates the ionic liquid into the polymeric matrix. Polymerization of a styrene and acrylonitrile monomers with the ionic liquid present would provide a styrene-acrylonitrile polymeric matrix having repeating units as shown in structure (II).

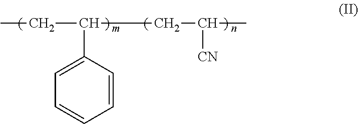

where m ranges from 60 to 90 wt. %, or 60 to 75 wt. %, or 60, 61, 62, 63, 64, 65, 66, 67, 68, 69, 70, 71, 72, 73 74, 75, 76, 77, 78, 79, 80, 81, 82, 83, 84, 85, 86, 87, 88, 89, 89 wt. % or any range or value there between, and n ranges from 25 to 45 wt %, or 25, 26, 27, 28, 29, 30, 31, 32, 33, 34, 35, 36, 37, 38, 39, 40 wt. %, or any range or value there between.

Polymerization of a styrene, acrylonitrile, and methyl methacrylate monomers with the ionic liquid present would provide a styrene-acrylonitrile-methyl methacrylate polymeric matrix having a repeating unit as shown in structure (III).

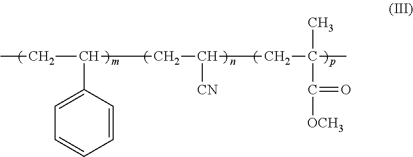

where m ranges from 30 to 80 wt. %, in particular 38 to 42 wt. %, or 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80 or any range or value there between, and n ranges from 10 to 40 wt. %, in particular 23 to 26 wt. %, or 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40 wt. % or any range or value there between, and p ranges from 10 to 40 wt. %, in particular 33 to 36 wt. %, or 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40 wt. % or any range or value there between.

### C. Applications for the Dielectric Polymeric Compositions

Any one of the dielectric polymeric compositions of the present invention can be used in a wide array of technologies and devices. The dielectric polymeric compositions can be made into films, sheets, or the like using known methods (e.g., casting). The ability to of the dielectric polymeric compositions or dielectric polymeric materials to generate an electric charge in response to applied mechanical stress and/or the ability to respond to an electric charge by changing stress can be useful in mechanical sensors, actuators and the like. In preferred embodiments, the dielectric polymeric material is a piezoelectric material.

Mechanical sensors can take advantage of the direct piezoelectric effect of the dielectric polymeric materials, in which changes in stress on the dielectric polymeric material cause a strain on the dielectric polymeric material causing displacement of the charge centers of the anions and cations in the material to produce an electric field. That electric field may be measured and used to determine the stress applied to the dielectric polymeric material. For example, a read-out circuit, such as a voltmeter or other circuit configured to measure a voltage between two points may be coupled to the dielectric polymeric material or electrodes in contact with the dielectric polymeric material. That read-out circuit may be coupled to processing logic configured to determine the voltage across the dielectric polymeric material (e.g., a piezoelectric material) resulting from an applied stress and, subsequently, to determine the applied stress by processing the determined voltage. For example, the determined voltage may be compared to a look-up table of values to determine the applied stress. As another example, a formula may be implemented in hardware or software to determine the applied stress based, at least in part, on the determined voltage. Such a formula may include known or measured quantities of the dielectric polymeric material, for example, a piezoelectric coefficient value or values.

Mechanical actuators may take advantage of the converse piezoelectric effect of the materials, in which application of electric field across the dielectric polymeric material (e.g., piezoelectric material) by a voltage source causes a strain on the dielectric polymeric material causing an expansion or contraction of the dielectric polymeric material to accommodate the changed strain. The electric field may be controlled to obtain desired a desired contraction and expansion of the dielectric polymeric material. For example, a voltage source, such as an AC or DC power source, and controller may be coupled to the dielectric polymeric material or electrodes in contact with the dielectric polymeric material. The controller may control the voltage source to generate a particular voltage to cause a specific expansion or contraction of the dielectric polymeric material. In some embodiments, the controller may implement a look-up table to correlate a desired change in shape or size of the dielectric polymeric material with a particular voltage value to apply using the voltage source. In some embodiments, the controller may implement a formula in hardware and/or software to determine a voltage value for application to the dielectric polymeric material to obtain a desired change in shape or size of the dielectric polymeric material. The formula may include known or measured quantities of the dielectric polymeric material, for example, a piezoelectric coefficient value or values.

A controller described with respect to the actuators and/or sensors described herein may include digital and/or analog control circuitry. An analog-to-digital converter (ADC) or digital-to-analog converter (DAC) may be used to interface digital control circuitry with analog control circuitry, digital control circuitry with analog devices, or vice versa. For example, a voltage source or a voltmeter coupled to a dielectric polymeric material may be configured to generate analog output values and/or receive analog input values, whereas the controller may be digital control circuitry. A digital-to-analog converter (DAC) may be used to interface an output control signal from the controller to the voltage source. An analog-to-digital converter (ADC) may be used to interface an output value from the voltmeter to the controller. The controller may include or be coupled to a tangible computer readable medium with code, such as in firmware and/or software, to configure the controller to perform certain functions relating to the control of or measurement of dielectric polymeric-based components (e.g., a piezoelectric-based component).

Although individual devices incorporating a dielectric polymeric material have been described, arrays of devices, each containing the same or different dielectric polymeric materials may be employed in a device. For example, a mechanical sensor may include an array of elements, each including dielectric polymeric materials. By determining stress applied to each of the elements a two dimensional representation of the applied stress may be generated. By determining the applied stress at each element as a function of time, a movement of the applied stress may be determined. For example, when a user input device includes an array of elements of dielectric polymeric material, a swipe gesture by a user on the user input device may be determined.

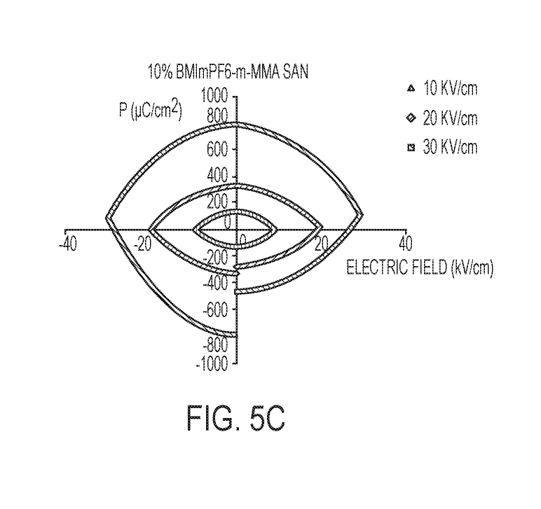

An example of such an array is shown in FIG. 6. Each actuator of array 600 may include dielectric polymeric material 602. Dielectric polymeric material 602 can be a dielectric polymeric material such as a polymeric matrix, where the polymeric matrix is derived from at least one polymerizable vinyl monomer and an ionic liquid that includes an organic cation and a balancing anion, wherein the ionic liquid is compatible with the at least one polymerizable vinyl monomer, and where the concentration of the ionic liquid in the dielectric polymeric composition (material) ranges from 0.5 wt. % to less than 30 wt. %. Each actuator can have a long axis oriented approximately perpendicular to a surface vector of substrate 608. Thus, the actuator may extend vertically from substrate 608, such as toward a user when substrate 608 is part of a display of an electronic device. Electrodes 604 and 606 may be located on opposite ends of the long axis. Electrodes 604 and 606 may be conductive materials such as, for example, a transparent conductive polymer such as PEDOT:PSS, transparent conductive oxides such as ITO, AZO, F:SnO2 and zinc-based oxides, graphene and graphene-like materials, metal-based nanowires and/or nanoparticles such as silver nanowires and copper nanowires, carbon nanotubes and other carbon-based structures, a metal mesh, a nanomesh, and or other conducting materials such as copper or aluminum or alloys thereof.

Non-limiting examples of actuators and sensors include ultrasonic devices such as ultrasonic oscillators, ultrasonic motors, pressure sensors, acoustic sensors, transducers, energy harvesters, or pyroelectric elements such as IR sensors. Dielectric polymeric materials (e.g., piezoelectric materials of the present invention) can also be incorporated into consumer electronic devices such as smartcards, RFID cards/tags, memory devices, non-volatile memory, standalone memory, firmware, microcontrollers, gyroscopes, microgenerators, power supply circuits, circuit coupling and decoupling, RF filtering, delay circuits, and RF tuners.

As used in any one of these or other technologies or devices, a dielectric polymeric material may be employed by coupling the dielectric polymeric material to a voltage source configured to apply an electric potential across the dielectric polymeric material. The voltage source and the dielectric polymeric material may be configured in different orientations such that the applied electric potential and the direction of stress or strain in the dielectric polymeric material are parallel, perpendicular, or at any other angle. By orienting the applied electric potential in parallel or perpendicular with the stress or strain, the dielectric polymeric material may be caused to expand or contract along certain directions in the application of certain voltages. By orienting the applied electric potential in other angles with the stress or strain, the dielectric polymeric material may be caused to shear.

Some detailed example embodiments for dielectric polymeric materials, such as any one of the dielectric polymeric compositions of the present invention, are described in more detail below. However, the provided detailed examples are only examples and not intended to be limiting on the disclosed dielectric polymeric compositions. Still further examples of a device using a dielectric polymeric-based mechanical sensor include a mobile computing device, a remote control for a television, controls within an automobile, and a switch such as a wall switch for a lighting device.

### 1. Mobile Computing Device

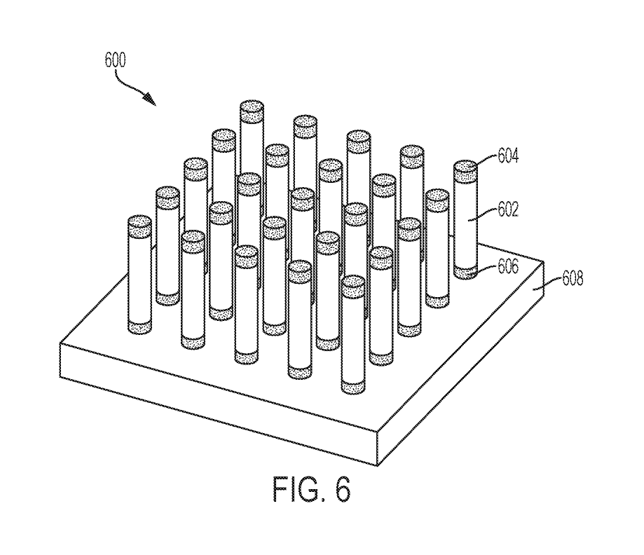

Referring to the array of FIG. 6, a stimulus, such as a voltage, may be applied across the electrodes 604 and 606 to create an electric field through the dielectric polymeric material 602. When the dielectric polymeric material 602 has piezoelectric properties, the electric field extending between the electrodes 604 and 606 may cause the dielectric polymeric material 602 to change shape. For example, an applied stimulus may be used to control a length of the dielectric polymeric material 602 along the long axis. Thus, a height (or length) of an actuator may be adjusted and controlled by applying appropriate stimuli to the actuators. Each actuator of the array 600 may be individually controlled through appropriate circuitry to apply different stimuli to different actuators to create a texture that a user can feel. That texture may be created, for example, overlying a display screen such that a person can feel a button or feel the texture of an animal's skin in a photograph. In one embodiment, static deflection of the actuators may be caused by applying a direct current (DC) signal as a stimulus for the actuators. Static deflection of the actuators is further described with reference to FIG. 7.

FIG. 7 is an illustration showing an array of dielectric polymeric-based actuators receiving a direct current (DC) stimulation to cause static displacement of the actuators according to one embodiment of the disclosure. An array 700 of actuators is shown with some of the actuators affected by an applied DC stimulus. An actuator 712 may include dielectric polymeric material 712C and electrodes 712A-B. No stimulus is applied to actuator 712, thus actuator 712 has a height reaching level 702, which is a rest height for actuators of the array 700. A positive DC signal may be applied to actuator 714 across electrodes 714A-B to cause the core material 714C to expand along its long axis. The actuator 714 thus reaches height level 706 above rest level 702. A negative DC signal may be applied to actuator 716 across electrodes 716A-B to cause the core material 716C to contract along its long axis. The actuator 716 thus reaches height level 704 below rest level 702. Although a positive signal is described as stretching an actuator and a negative signal is described as shrinking an actuator, the positive and negative signals are relative and may be switched. Thus, alternatively, a negative DC signal may shrink an actuator and a positive signal may stretch an actuator. By individually controlling actuators 712, 714, and 716 (and other actuators not shown) of the array 700, a texture may be generated at a surface of an electronic device, such as a smart phone or mobile computing device.

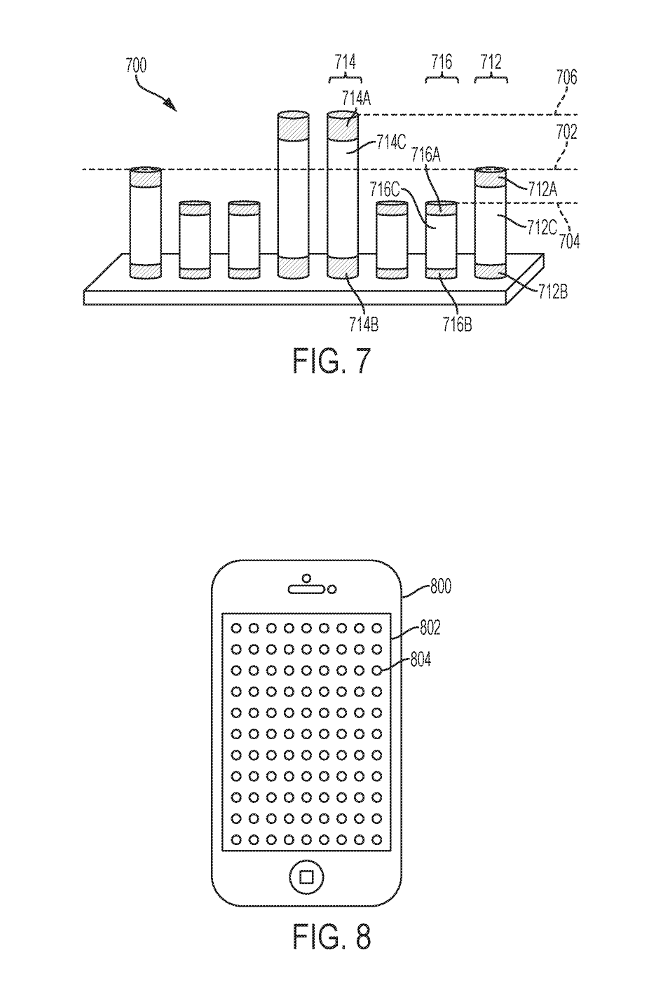

A smart phone with a display screen integrating an array of actuators, such as the array shown in FIGS. 6 and 7, is shown in FIG. 8. FIG. 8 is an illustration showing an array of cylindrical dielectric polymeric material-based actuators integrated into a display of an electronic device according to one embodiment of the disclosure. A smart phone 800 may include a display device 802. An array 804 of dielectric polymeric-based actuators may be integrated with the display device 802 to provide a user with addressable and localized touch feedback. In one embodiment, the array 804 may be constructed of transparent materials and integrated over the display device 802. Although a smart phone is illustrated in FIG. 8, the array 804 may also be integrated into any display device of any electronic device in the same manner. For example, the array 804 of dielectric polymeric-based actuators may be integrated into a smart watch, a tablet computer, a laptop computer, a cellular phone, a remote control, or a television screen. Further, the array 804 of dielectric polymeric-based actuators may be integrated into other components separate from a display device for reading by the visually-impaired.

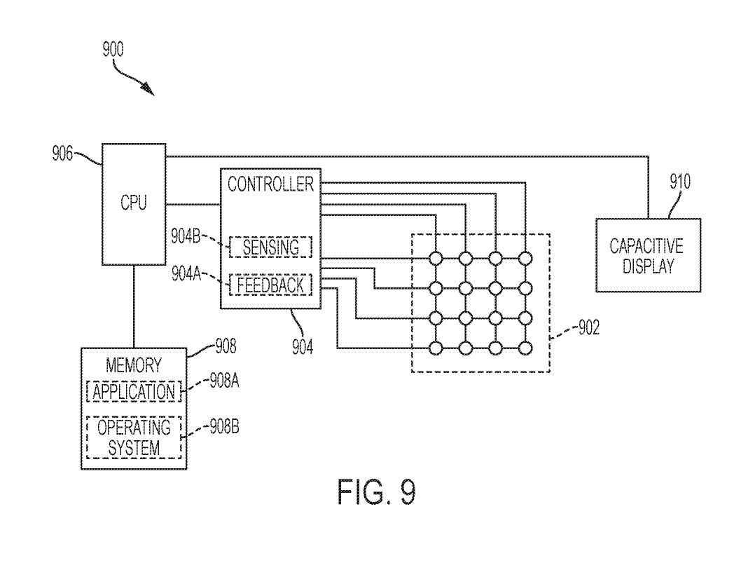

Control of an array of dielectric polymeric-based actuators to create textures through electrostatic deflection may be performed from a controller coupled to the array as shown in FIG. 9. FIG. 9 is a block diagram showing operation of an array of dielectric polymeric-based actuators from a controller according to one embodiment of the disclosure. A system 900 may include an array 902 of dielectric polymeric-based actuators, such as the arrays described above with reference to FIGS. 6 and 7. The array 902 may be coupled to a controller 904, which may be configured to apply stimulus to the actuators of array 902. The controller 904 may be configured to individually address actuators of the array 902, such that the controller 904 can manipulate a height of individual actuators within the array 902. The controller 904 may also be configured to address actuators of the array 902 by groups of, for example, 4 or 16 actuators at a time. In one embodiment, the array 902 may be configured similar to a dynamic random access memory (DRAM) module with word and bit lines arranged to allow addressing one or more actuators of the array 902.

The controller 904 may generate control signals for providing touch feedback through the array 902 and/or receiving sensing signals for determining user input through the array 902. The controller 904 may coordinate operation of the array 902 with a processor 906 and memory 908. In one configuration, the processor 906 may execute an application 908A or an operating system 908B residing within the memory 908. Application code within the application 908A may include code for providing touch feedback to a user, such code may apply a texture to a displayed image. The operating system 908B executing on the processor 906 may cause the execution of the application 908A including code to provide the touch feedback. In another configuration, the operating system 908B may include code to provide touch feedback as part of an application programming interface (API) accessed by the application 908A. Thus, for example, when the application 908A generates a user dialog box with buttons, the operating system 908B may include code to automatically apply touch feedback to that user dialog box.

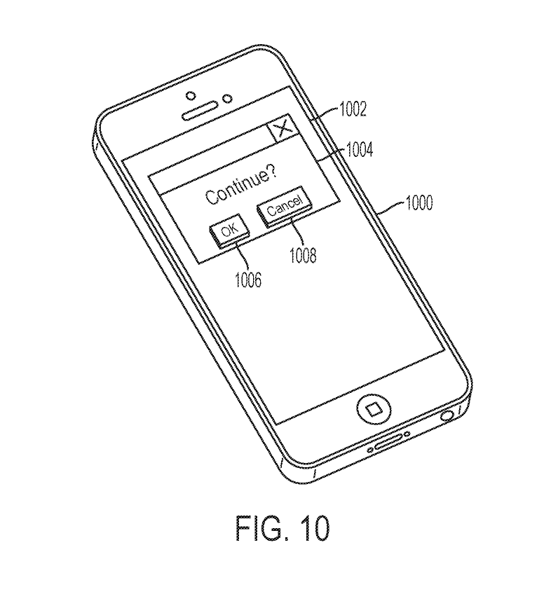

An example of the textures produced through static deflection of the array 902 is illustrated in FIG. 10. FIG. 10 is an illustration showing a texture presented on a display of an electronic device using an array of dielectric polymeric material-based actuators receiving a direct current (DC) stimulation according to one embodiment of the disclosure. A mobile phone 1000 may include a display device 1002. During operation of the mobile phone 1000, an application executing on the mobile phone 1000 may display a dialog box with an “OK” or “Cancel” selection indicated by buttons 1006 and 1008, respectively. The dielectric polymeric material-based actuators located at the position of the buttons 1006 and 1008 may be stimulated to generate a texture of a raised surface at the location of the buttons 1006 and 1008. The texture may provide sensation to a user operating the smart phone 1000 and allow them to quickly find the buttons 1006 and 1008. Further, the actuators may be programmed to provide a user with touch feedback in response to pressing the buttons 1006 and 1008, such as by depressing the texture of the button 1006 or 1008 depending on which button was pressed.

Referring back to FIG. 9, the processor 906 may provide touch feedback by accessing feedback module 904A within the controller 904. The feedback module 904A may receive instructions from the processor 906, in which the instructions include a type of touch feedback, a strength of the touch feedback, and/or a location for the touch feedback. The controller 904 may decode the instruction and provide appropriate stimuli to the array 902 of dielectric polymeric material-based actuators by applying a DC voltage to the identified actuator in the array 900. The DC voltage may be generated by the controller 904 or the controller 904 may connect the actuator to an external voltage source (not shown).

The processor 906 may also interact with the controller 904 to receive input from a user through a sensing module 904B within the controller 904. The sensing module 904B may monitor actuators in the array 902 for changes in characteristics of the actuators that may result from a user applying pressure to the array 902 and causing the actuators to deflect, compress, or otherwise change shape. The change in shape of the actuator may cause, for example, a resistance of the actuator to change. That change in resistance may be detected by the sensing module 904B to determine when and where pressure was applied in the array 902. The sensing module 904B may then communicate to the processor 906 a signal indicating a location of the user's input and an amount of pressure applied by the user. The processor 906 may then provide the user input to the application 908A and/or the operating system 908B executing on the processor 906, which may take action in response to the user input. For example, the sensing module 904B may collect data from the array 902 over a period of time and determine if a swiping motion is received and then take corresponding action, such as to turn pages on a display of a mobile computing devices to page through an e-book.

In one embodiment, user input may be received through a capacitive layer 510 in the display device in addition to or in alternative to input from the dielectric polymeric material-based actuators. The capacitive layer 910 may be coupled to the processor 906, or through a display controller (not shown), to provide the user input to the application 908A and/or the operating system 908B. The processor 906 may generate instructions for providing touch feedback in response to user input received from the capacitive layer 910. In other embodiments, no capacitive layer 910 may be present and all user input may be received through the array 902.

### 2. Switch Using Dielectric Polymeric Material-Based Elements

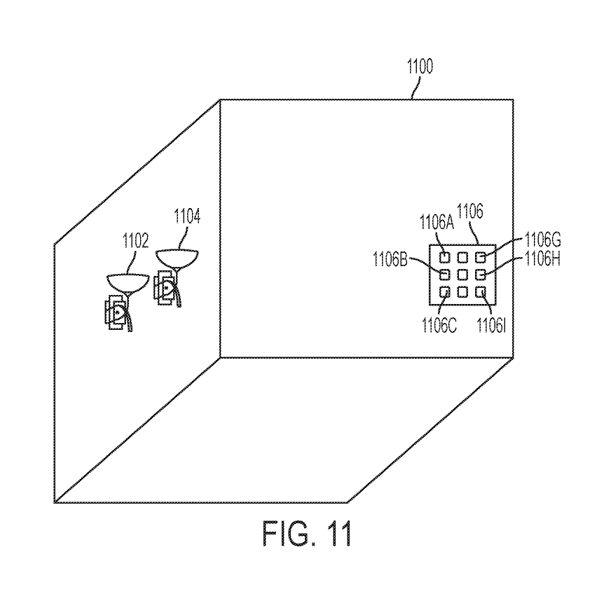

An array of dielectric polymeric material-based sensors may be used in a user input device to control electronic devices or provide other user input. One such user input device may be a wall switch for operating lighting fixtures as shown in FIG. 11. FIG. 11 is an illustration of a room with a switch with an array of dielectric polymeric material-based sensors according to one embodiment of the disclosure. A room 1100 may include lighting fixtures 1102 and 1104 and a wall switch 1106. The switch 1106 may include dielectric polymeric material-based sensors 1106A-I. A controller may be coupled to the sensors 1106A-I to receive user input. For example, when a user swipes their hand in an upward motion across the sensors 1106A-I, the controller may detect an changing voltage first on sensors 1506C, 1506F, and 1506I, second on sensors 1506B, 1506E, and 1506H, and then on sensors 1506A, 1506D, and 1506G. The controller may interpret this as a swipe upwards across the switch 1106 and control a voltage source or dimmer for the lighting fixtures 1102 and 1104 to increase brightness. The controller may similarly detect a swipe downwards across the switch 1106 to decrease brightness. Although a wall switch is described with reference to a dielectric polymeric-based sensor, any user input device may incorporate one or more dielectric polymeric material-based elements. Other examples include input devices on a mobile computing device, input devices integrated into a screen of a mobile computing device, input devices for computers such as mice and keyboards, input devices on remote controls, input devices on media playback devices such as speakers and headphones, input devices on office telephones, input devices in automobiles, and the like.

### 3. Energy Harvesting

The dielectric polymeric material of the present invention can be incorporated into devices or components that are frequently under stress, and that dielectric polymeric material is used to harvest energy that is otherwise expended and lost. For example, dielectric polymeric materials may be incorporated into shoes, such that a user's steps may apply stress to the dielectric polymeric materials. Energy can be harvested from the applied stress and stored in an energy storage device such as a battery. As another example, dielectric polymeric materials may be incorporated into a floor on which users frequently step. Although user steps are described as the process used for harvesting energy in these examples, energy may be harvested from other actions. For example, ambient noise or vibration may be used for energy harvesting through an appropriately-configured device comprising the dielectric polymeric materials described herein.

### 4. Microscopy

Microscope tips for high-resolution imaging, such as atomic force microscopy (AFM) and scanning tunneling microscopy (STM), may employ tips with dielectric polymeric materials such as those described herein. The dielectric polymeric material may be used in the microscope tip to apply a downward force on the tip to maintain proximity to a sample being imaged by the microscope.

### 5. Transformers

An alternating current (AC) transformer may use dielectric polymeric materials such as those disclosed herein to convert one form of electrical energy to another form of electrical energy. For example, an input AC voltage may be applied to a dielectric polymeric material causing alternating stress in the dielectric polymeric material leading to vibration of the dielectric polymeric material. The shape and characteristics of the dielectric polymeric material may be selected to obtain a vibration frequency at a desired frequency. An output AC voltage from a different section of the dielectric polymeric material may be a voltage of higher or lower frequency than the input AC voltage. Such a transformer may be used in power distribution networks or in power circuitry for consumer electronics.

### EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### General Information

Materials were made or purchased as shown in Table 1. Proton nuclear magnetic resonance (1H NMR) spectroscopy was used to determine the chemical compositions of co- and terpolymers and ionic liquid containing polymer compositions. The morphology of the ionic liquid containing polymer compositions were analyzed by transmission electron microscopy (TEM) technique. For electrical measurements, films were electroded with a conductive silver paste composition. The dielectric properties were measured by a Novocontrol Alpha A High Frequency Impedance Analyzer (frequency range 100 HZ-1 MHz) at room temperature. P-E hysteresis loops were measured using Radiant Precision Materials Analyzer. During measurement, films were immersed in silicon oil to reduce arcing.

TABLE 1

| COMPONENT | CHEMICAL DESCRIPTION | SOURCE |
|---|---|---|
| SAN 2548 | Styrene-acrylonitrile copolymer | SABIC |
| | | Innovative |
| | | Plastics |
| MMA SAN | Methyl methacrylate-styrene- | SABIC |
| 821222 | acrylonitrile terpolymer | Innovative |
| | | Plastics |
| MMA | Methyl methacrylate(≥ 99%) | Sigma- |
| | | Aldrich ® |
| Styrene | Styrene (≥ 99%) | Sigma- |
| | | Aldrich ® |
| Acrylonitrile | Acrylonitrile (≥ 99%) | Sigma- |
| | | Aldrich ® |
| AIBN | Azobisisobutyronitrile (98%) | Avra Synthesis |
| | | Pvt. Ltd. |
| BMImPF₆ | 1-butyl-3-methylimidazolium | Sigma- |
| | hexafluorophosphate (≥ 97%) | Aldrich ® |

### Example 1

### Synthesis of Dielectric Polymeric Composition

Ionic liquid containing polymer compositions were synthesized by dissolving the ionic liquid, 1-butyl-3-methylimidazolium hexafluorophosphate (BMIMPf6, See, chemical structure (I)) in vinyl monomers in low concentration (≤20 wt %) as shown in Table 2, followed by polymerizing the vinyl monomers by free radical bulk polymerization technique. Films were casted in the prepolymer stage and dried to remove the unreacted monomers. Table 2 also lists concentrations of co-polymer and terpolymers without ionic liquid that were used as comparative samples (Sample Nos. 1 and 4).

TABLE 2

| | | | | ACRYLO- | | |
|---|---|---|---|---|---|---|
| | | MMA | STYRENE | NITRILE | AIBN | BMImPF6 |
| No. | Sample Composition | (wt %) | (wt %) | (wt %) | (wt %) | (wt %) |
| 1 | syn-SAN | — | 75 | 25 | 0.2 | — |
| 2 | 10% BMImPF₆-m-SAN | — | 75 | 25 | 0.2 | 10 |
| 3 | 40% BMImPF₆-m-SAN | — | 75 | 25 | 0.2 | 40 |
| 4 | syn-MMA SAN | 35 | 40 | 25 | 0.2 | — |
| 5 | 5% BMImPF₆-m-MMA SAN | 35 | 40 | 25 | 0.2 | 5 |
| 6 | 10% BMImPF₆-m-MMA SAN | 35 | 40 | 25 | 0.2 | 10 |
| 7 | 20% BMImPF₆-m-MMA SAN | 35 | 40 | 25 | 0.2 | 20 |

### Example 2

### Characterization of Dielectric Polymeric Compositions

¹H NMR.

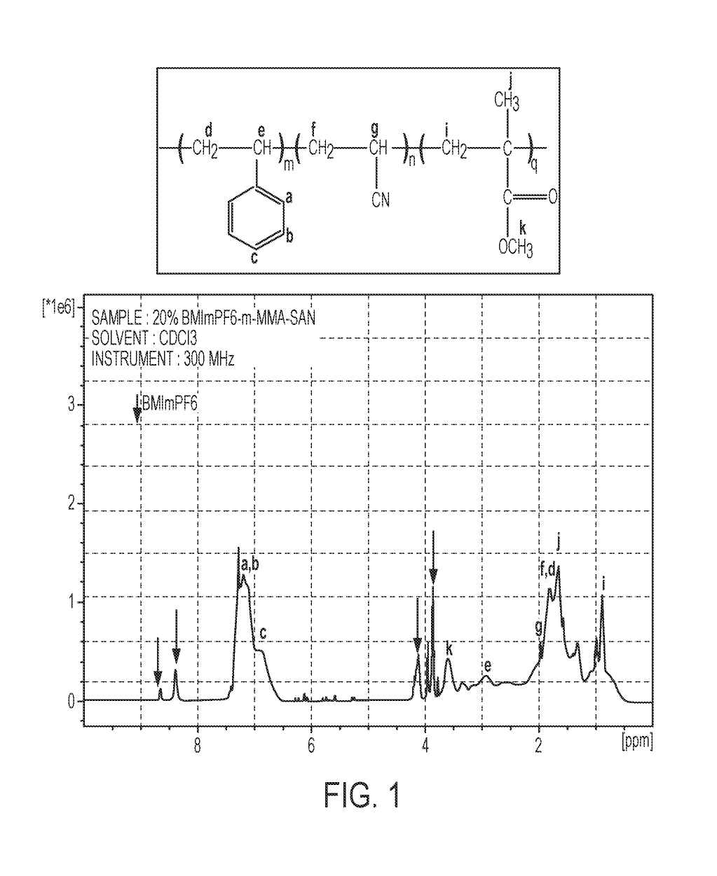

The incorporation of the ionic liquid (BMImPF6) in the polymer matrix was confirmed by proton nuclear magnetic resonance (¹H NMR). Peaks corresponding to the protons of the ionic liquid overlapped with those of peaks known to be associated with MMA SAN except in 8-9 ppm region. The well resolved peaks in this region were utilized to identify the protons in BMImPF6. FIG. 1 shows ¹H NMR spectra of Sample 7 (20 wt % BMImPF6 in MMA SAN).

Optical Clarity.

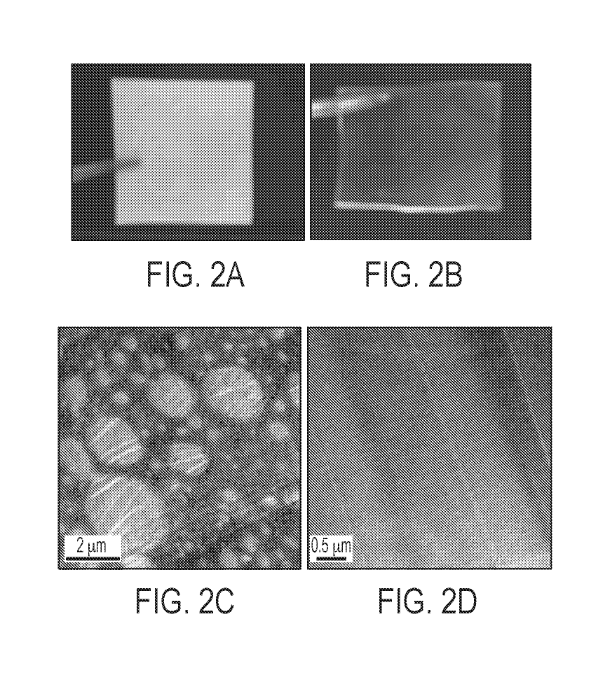

Optical clarity was used to determine the miscibility of the blends. BMImPF6 containing MMA SAN films were transparent (Samples 5-7), while ionic liquid modified SAN based films (Samples 2 and 3) were opaque. FIG. 2A and FIG. 2B show the optical clarity of Sample 2 (10% BMImPF6-m-SAN) and Sample 6 (10% BMImPF6-m-MMA) SAN. From the data, Sample 6 is transparent and Sample 2 is opaque. FIGS. 2C and 2D display the transmission electron micrographs of Samples 2 and 6 respectively. In Sample 2 (10% BMImPF6-m-SAN, FIG. 2C), dispersed ionic liquid domains were visible with a wide domain size distribution. In contrast, domains are not seen in Sample 6 (10% BMImPF6-m-MMA-SAN, FIG. 2D). Favorable compatibility of MMA unit with BMIMPF6 resulted disappearance of the ionic liquid phase in Sample 6 (10% IL-m-MMA SAN) composition. The formation of larger domains of the ionic liquid phase caused loss of clarity in Sample 2 10% IL-m-SAN).

### Example 3

### Electrical Measurement

Electrical Measurement

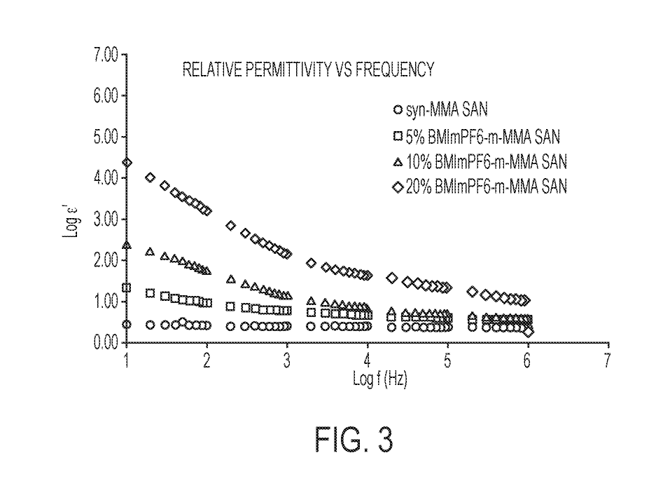

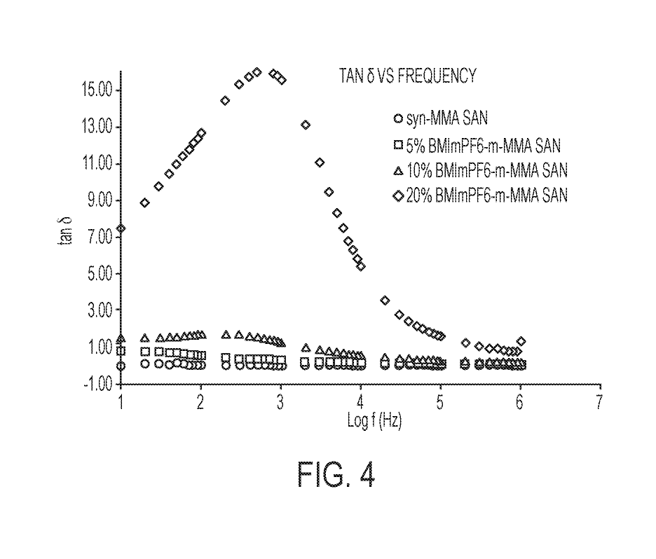

Piezoelectric behavior of the Samples 1-6 was assessed by measuring dielectric constant and remanent polarization. FIG. 3 shows dielectric constant as a function of frequency for MMA-SAN and BMImPF₆ containing MMA-SAN compositions listed in Table 2. Circle line monikers represents data for Comparative Sample 4, square line monikers represents data for Sample 5, triangle monikers represents data for Sample 6, and diamond monikers represents data for Sample 7. FIG. 4 shows graphs of tan (delta) versus frequency for a comparative polymeric sample and three dielectric polymeric compositions of the present invention. Circle line monikers represents data for Comparative Sample 4, square line monikers represents data for Sample 5, triangle monikers represents data for Sample 6, and diamond monikers represents data for Sample 7. The dielectric constant of the ionic liquid containing compositions (Samples 5, 6, and 7) was significantly increased compared to neat MMA SAN (Comparative Sample 4). For example, dielectric constant of Sample 6 (10% BMImPF₆-m-MMA SAN) reached 58 at 100 Hz which is more than 19 times improvement as compared to Comparative Sample 4 (MMA SAN matrix), which did not include the ionic liquid. The dielectric constant of the compositions increases with decreasing frequency and high dielectric dispersion was observed at low frequency. The composition containing higher concentration of ionic liquid (e.g., Sample 7, 20 wt. % BMImPF₆) exhibits stronger dielectric dispersion as compared to that with Sample 6 and 7 (e.g., 5 and 10 wt. % BMImPF₆ content). Ionic liquids are known to suffer from high dielectric loss attributed to the long range motion of the ions. The insulating polymer matrix reduced the dielectric loss of ionic liquid as indicated by a substantial decrease in dielectric loss in Sample 6 (5 wt. % BMImPF₆-m-MMA SAN) compared to that in Sample 7 (20 wt. % BMIMPF₆-m-MMA SAN). The dielectric properties of the polymer compositions are illustrated in Table 3.

TABLE 3

| | | | | | Polarization | |
|---|---|---|---|---|---|---|
| | | | Dielectric | Dielectric | Electric | Remanent |
| | | Tg | constant | breakdown | field | polarization |
| No. | SAMPLE | (° C.) | @ 1 KHz | (kV/cm) | (KV/cm) | (μC/cm²) |
| 1 | SAN | 109 | 2.4 | — | 400 | 0.08 |
| 2 | 10% BMImPF6-m-SAN | 96 | 29 | 10-15 | 10 | 645 |
| 3 | 40% BMImPF6-m-SAN | 100 | 1600 | Did not | No remanent polarization | |
| | | | | withstand | | |
| | | | | voltage | | |
| 4 | MMA SAN | 97 | 2.6 | >1000 | 1000 | 0.15 |
| 5 | 5% BMImPF6-m-MMA SAN | 62 | 6 | 50-60 | 50 | 80 |
| 6 | 10% BMImPF6-m-MMA SAN | 50 | 15 | 30-35 | 30 | 783 |
| 7 | 20% BMImPF6-m-MMA SAN | 7 | 144 | Did Not | No remanent polarization | |
| | | | | withstand | | |
| | | | | voltage | | |

Remanent polarization for commercial PVDF films measured is 10 μC/cm² @ 2200 KV/cm.

From the data, it was evident that Samples 2, 5 and 6 with the ionic liquid content below 20 wt % were able to with stand an electric field. Sample 7 (20% BMImPF₆-m-MMA SAN) showed ionic conductivity. It was not possible to determine the dielectric breakdown of the neat polymer matrices due to the limited voltage supply capability of the measurement setup.

P-E Hysteresis.

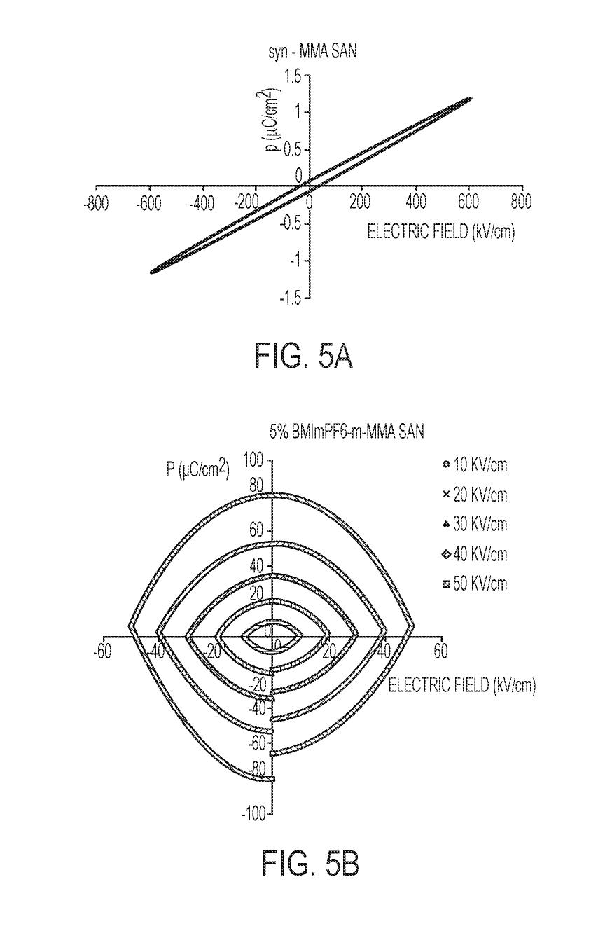

P-E hysteresis plots (polarization, P (μC/cm²) vs applied electric field, E (KV/cm)) of MMA SAN and BMImPF₆-m-MMA SAN compositions are shown in FIGS. 5A-5C. All measurements were taken at room temperature. FIG. 5A is Comparative sample 4 (MMA SAN), which showed no hysteresis properties. FIG. 5B is dielectric polymeric composition Sample 5 (5% BMImPF₆-m-MMA SAN) with the outer loop being a 50 KV/cm applied electric field and each loop inside being 40, 30, 20 and 10 KV/cm, respectively. FIG. 5C is dielectric polymeric composition Sample 6 (10% BMImPF₆-m-MMA SAN), with the outer loop being a 30 KV/cm applied electric field and each loop inside being 20 and 10 KV/cm, respectively.

Compared to the compositions without ionic liquid, significant improvement in remanent polarization was evident with BMImPF₆ containing polymer compositions and the voltage required to achieve the polarization is drastically reduced compared to neat SAN, MMA SAN and also commercial PVDF (See, Table 3).

1. A dielectric polymeric composition comprising:
(a) a polymeric matrix, wherein the polymeric matrix is derived from at least one polymerizable vinyl monomer; and
(b) an ionic liquid comprising an organic cation and a balancing anion,
wherein the ionic liquid is compatible with the at least one polymerizable vinyl monomer,
wherein the concentration of the ionic liquid in the dielectric polymeric composition ranges from 0.5 wt. % to less than 30 wt. %.

2. The dielectric polymeric composition of claim 1, wherein the dielectric polymeric composition is capable of a polarization of greater than 30 μC/cm² upon the application of an electric field of less than 30 kilovolts/centimeter.

3. The dielectric polymeric composition of claim 1, wherein the ionic liquid is incorporated into the polymeric matrix.

4. The dielectric polymeric composition of claim 1, wherein the polymeric matrix is formed, in situ, in the presence of the ionic liquid and in the absence of a solvent.

5. The dielectric polymeric composition of claim 1, wherein the ionic liquid concentration ranges from 5 wt. % to 20 wt. %.

6. The dielectric polymer composition of claim 1, wherein the dielectric polymeric composition is a Tg miscible blend.

7. The dielectric polymer composition of claim 1, wherein the ionic liquid imparts elasticity to the composition.

8. The dielectric polymeric composition of claim 1, wherein the organic cation comprises a substituted or unsubstituted imidazole compound, a substituted or unsubstituted N-alkylpyridinium compound, a substituted or unsubstituted N,N dialkyl pyrrolidinium compound, a substituted or unsubstituted piperidinium compound, a substituted or unsubstituted morpholinium compound, a trialkyl sulfonium compound, a tetraalkyl phosphonium compound, an aryl phosphonium compound, or any combination thereof.

9-11. (canceled)

12. The dielectric polymeric composition of claim 1, wherein the balancing anion comprises a halogenated phosphate, a chlorate, an alkyl sulfate, a dicyanamide, a bis(trifluoromethanesulfonyl)imide, a bis(pentafluoroethanesulfonyl)imide, a tetrafluoroborate, a trifluoromethanesulfonate, a trifluoromethaneacetate, carboxylate, preferably hexafluorophosphate.

13. The dielectric polymeric composition of claim 1, wherein the polymerizable vinyl monomer has a general structure of: 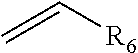
where R⁶ comprises a hydrogen, an alkyl group, an aryl group, a substituted aryl group, an alkylaryl, a cyano group or any combination thereof.

14. The dielectric polymeric composition of claim 13, wherein the polymeric matrix is a copolymer derived from two vinyl monomers.

15. The dielectric polymeric composition of claim 1, wherein at least one of the vinyl monomers comprises styrene or derivatives thereof, acrylonitrile or derivatives thereof, or any mixture thereof.

16. The dielectric polymeric composition of claim 15, comprising 70 wt. % to 80 wt. % of styrene, 20 wt. % to 30 wt. % of acrylonitrile and 5 wt % to 15 wt. % of ionic liquid.

17. The dielectric polymeric composition of claim 1, wherein the polymeric matrix is a terpolymer derived from an acrylate monomer and the two vinyl monomers.

18. The dielectric polymeric composition of claim 17, wherein at least one of the acrylate monomers comprises methyl acrylate, ethyl acrylate, methacrylates, methyl methacrylate, butyl methacrylate, or any combination thereof.

19. The dielectric polymeric composition of claim 18, comprising 30 wt. % to 40 wt. % of methyl methacrylate, 35 wt. % to 45 wt. % of styrene, 20 wt. % to 30 wt. % of acrylonitrile and 5 wt. % to 20 wt. % of ionic liquid.

20. The dielectric polymer composition of claim 1, wherein the wherein the dielectric polymeric composition consists essentially of or consists of the ionic liquid and the polymeric matrix

21-22. (canceled)

23. The dielectric polymeric composition of claim 1, wherein the composition has:
(i) a glass transition temperature Tg of 50 to 96° C.;
(ii) a dielectric constant (ε) at 1 KHz of 5 to 30;
(iii) a dielectric breakdown (kV/cm) of 10 to 60; and/or
(iv) a remanent polarization (μC/cm²) of 30 to 785 after removal of an electric field of 10 to 30 KV/cm.

24. (canceled)

25. A piezoelectric device comprising the dielectric polymeric composition of claim 1, wherein the device is a piezoelectric sensor, a piezoelectric transducer, a piezoelectric energy harvester, or a piezoelectric actuator.

26. (canceled)

27. A method for making, in situ, a dielectric polymeric composition of claim 1, the method comprising:
(a) subjecting a mixture comprising an ionic liquid and polymeric precursor material comprising at least one polymerizable vinyl monomer to polymerization conditions, wherein the ionic liquid is solubilized in the at least one polymerizable vinyl monomer; and
(b) forming a polymeric matrix wherein the ionic liquid is miscible or partially miscible with the polymeric matrix.

28-81. (canceled)
